(19) United States
(12) Patent Application Publication
(10) Pub. No.: US 2011/0298479 A1
(43) Pub. Date: Dec. 8, 2011

(54) Capacitive coordinate input device, capacitive coordinate input method, and information device

(76) Inventor: Kenichi Matsushima, Chiba-shi (JP)

(21) Appl. No.: 13/134,272

(22) Filed: Jun. 3, 2011

(30) Foreign Application Priority Data
Jun. 7, 2010 (JP) 2010-130483

(51) Int. Cl. G01R 27/26

(52) U.S. Cl. 324/658

(57) ABSTRACT

Provided are a capacitive coordinate input device and a capacitive coordinate input method for detecting at high speed the position of an object, such as a human finger or a pen, by detecting a change in capacitance at each intersection of a plurality of electrodes arranged corresponding to two-dimensional coordinates. Tri-state driving is performed such that, immediately after a voltage of a transmitting electrode is changed, impedance of other transmitting electrodes having no voltage change is temporarily increased.

### BACKGROUND OF THE INVENTION

1. Field of the Invention

The present invention relates to a capacitive coordinate input device and a capacitive coordinate input method for detecting coordinates of an object, such as a human finger, by detecting a change in capacitance at each intersection of a plurality of electrodes arranged corresponding to two-dimensional coordinates, and also relates to an information device including the capacitive coordinate input device.

2. Description of the Related Art

It is known that when an object such as a human finger approaches two neighbor electrodes, a capacitance between the electrodes is changed. Various disclosed capacitive coordinate input devices, including capacitive touch sensors, apply this principle to the detection of the capacitance at each intersection of the plurality of electrodes arranged corresponding to the two-dimensional coordinates in a detection region, and some of the capacitive coordinate input devices have been put into practical use (see, for example, Japanese Patent Translation Publication No. 2003-526831 and US 2007/0257890).

Referring to FIGS. 14 and 15, an example of the conventional capacitive coordinate input device is described.

In the example of FIG. 14, transmitting electrodes 104 corresponding to vertical coordinates and receiving electrodes 105 corresponding to horizontal coordinates are arranged in a detection region 103 of a support 102 so as to be orthogonal to one another. The transmitting electrodes 104 are selectively applied with a periodic AC voltage from a bi-state drive section 1402 one by one (i.e., line-sequential driving). The AC voltage is transmitted to the receiving electrode 105 by capacitive coupling at the intersection of the transmitting electrode 104 and the receiving electrode 105. Based on a current flowing to the receiving electrode 105 having a virtual ground, a current measurement section 107 detects a value associated with the capacitive coupling at each of the corresponding intersections, and outputs the detected value to a processing section 108. Here, various methods for determining such a weak AC current in a cumulative manner are disclosed, for example, a method involving switching accumulation capacitors in synchronization with the periodic AC voltage to be selectively and sequentially applied to the transmitting electrodes 104, and a method involving superimposing a demodulation waveform for accumulation.

The processing section 108 determines the position of a detection target object based on, for example, a weighted average of the values or changes in values that are associated with the capacitive coupling at the respective intersections of the electrodes corresponding to the two-dimensional coordinates.

In a conventional capacitive coordinate input device 1401 having the configuration described above, as illustrated in FIG. 15, the transmitting electrodes are subjected to the line-sequential driving to be selectively and sequentially driven one by one. However, non-selected transmitting electrodes are also driven with a constant voltage, which causes a problem that, when a transmitting electrode is selected and driven, a relevant current flows but makes a detour to the non-selected transmitting electrodes and hence it takes a longer time to arrive at the receiving electrode. The reason why the constant voltage is necessary is that high impedance of the non-selected transmitting electrodes affects a current to be received if the voltage varies due to noise or the like, and the capacitive coordinate input device is thus required to set the non-selected transmitting electrodes to be low impedance with a constant voltage.

### SUMMARY OF THE INVENTION

Therefore, the present invention provides the following device and method for solving the above-mentioned problem.

In the device and the method, when a transmitting electrode is selected and driven, other non-selected transmitting electrodes are temporarily increased in impedance so that the influence of noise may be eliminated while preventing a current from making a detour to the non-selected transmitting electrodes, to thereby reduce a time necessary for the current to arrive at a receiving electrode and achieve high-speed detection.

A capacitive coordinate input device according to the present invention includes: a support; a plurality of transmitting electrodes corresponding to one dimension in a detection region on the support and a receiving electrode corresponding to another dimension; a tri-state drive section for driving the plurality of transmitting electrodes so as to change a voltage of at least one transmitting electrode that is selected from among the plurality of transmitting electrodes and to temporarily increase drive impedance of non-selected transmitting electrodes immediately after the change in the voltage of the at least one selected transmitting electrode; a current measurement section for measuring one of a current and a charge amount supplied from the receiving electrode, in synchronization with the driving of the plurality of transmitting electrodes; and a processing section for determining input coordinates in the detection region based on one of a value of the current and the charge amount measured by the current measurement section.

A capacitive coordinate input method according to the present invention includes: tri-state-driving a plurality of transmitting electrodes corresponding to one dimension in a detection region for detecting approach of an object, so as to change a voltage of at least one transmitting electrode that is selected from among the plurality of transmitting electrodes and to temporarily increase drive impedance of non-selected transmitting electrodes immediately after the change in the voltage of the at least one selected transmitting electrode; performing current measurement on one of a current and a charge amount supplied from a receiving electrode corresponding to another dimension in the detection region, in synchronization with the tri-state driving of the plurality of transmitting electrodes; and determining input coordinates in the detection region based on one of a value of the current and the charge amount obtained by the current measurement.

According to the present invention, a signal delay time from the transmitting electrode to the receiving electrode can be reduced to increase a detection speed for smooth input.

Besides, it is possible to realize the capacitive coordinate input device and the capacitive coordinate input method, in which the number of charge/discharge cycles can be increased to reduce the influence of noise or decrease a drive voltage.

### BRIEF DESCRIPTION OF THE DRAWINGS

In the accompanying drawings:

FIG. 1 is a block diagram illustrating a preferred embodiment of a capacitive coordinate input device according to the present invention;

FIGS. 2A and 2B are block diagrams each illustrating an embodiment of a tri-state drive section according to the present invention;

FIG. 3 is a block diagram illustrating an embodiment of a current measurement section according to the present invention;

FIG. 4 is a block diagram illustrating an embodiment of a processing section according to the present invention;

FIG. 5 is a process flow chart illustrating a preferred embodiment of a capacitive coordinate input method according to the present invention;

FIG. 6 is a timing chart of a timing generation section according to the present invention;

FIG. 7 is a timing chart in a tri-state driving step and a current measurement step according to the present invention;

FIG. 8 is a timing chart illustrating drive waveforms of transmitting electrodes according to the present invention;

FIG. 9 is a conceptual diagram illustrating an equivalent circuit in a detection region according to the present invention;

FIGS. 10A and 10B are characteristic graphs showing the effects of the present invention;

FIGS. 11A to 11D are timing charts illustrating other examples of the drive waveforms of the transmitting electrodes according to the present invention;

FIG. 12 is a block diagram illustrating an example of an information device using the present invention;

FIGS. 13A to 13D illustrate examples of the information device using the present invention;

FIG. 14 is a block diagram of a conventional capacitive coordinate input device; and

FIG. 15 is a timing chart illustrating an operation of the conventional capacitive coordinate input device.

### DETAILED DESCRIPTION OF THE PREFERRED EMBODIMENT

A capacitive coordinate input device according to the present invention includes: a support; a plurality of transmitting electrodes corresponding to one dimension in a detection region on the support and a receiving electrode corresponding to another dimension; a tri-state drive section for driving the plurality of transmitting electrodes so as to change a voltage of at least one transmitting electrode that is sequentially selected from among the plurality of transmitting electrodes and to temporarily increase drive impedance of non-selected transmitting electrodes immediately after the change in the voltage of the at least one selected transmitting electrode; a current measurement section for measuring one of a current and a charge amount supplied from the receiving electrode, in synchronization with the driving of the plurality of transmitting electrodes; and a processing section for determining input coordinates in the detection region based on one of a value of the current and the charge amount measured by the current measurement section, and managing a status and a sequence of the overall capacitive coordinate input device.

A capacitive coordinate input method according to the present invention includes: tri-state-driving a plurality of transmitting electrodes corresponding to one dimension in a detection region for detecting approach of an object, so as to change a voltage of at least one transmitting electrode that is selected from among the plurality of transmitting electrodes and to temporarily increase drive impedance of at least one non-selected transmitting electrode immediately after the change in the voltage of the at least one selected transmitting electrode; performing current measurement on one of a current and a charge amount supplied from a receiving electrode corresponding to another dimension in the detection region, in synchronization with the tri-state driving of the plurality of transmitting electrodes; and determining input coordinates in the detection region based on one of a value of the current and the charge amount obtained by the current measurement.

The features of the present invention are described below based on the difference from the related art.

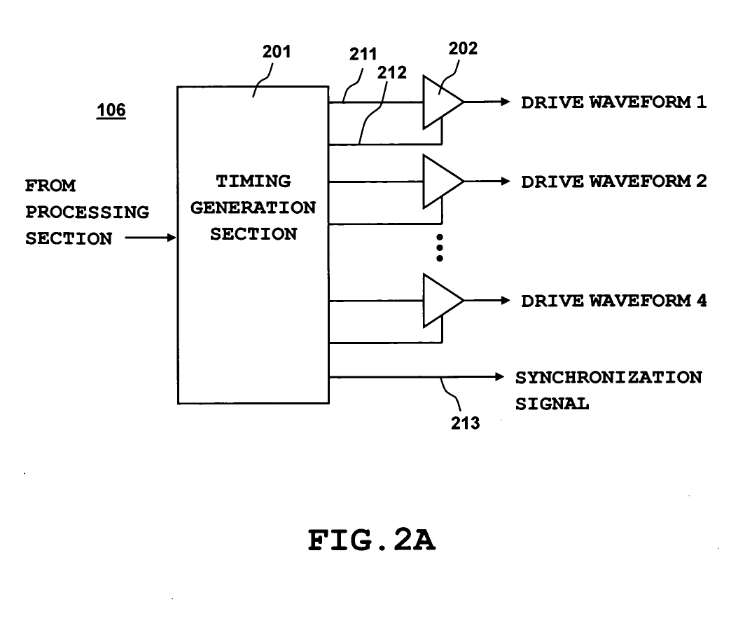

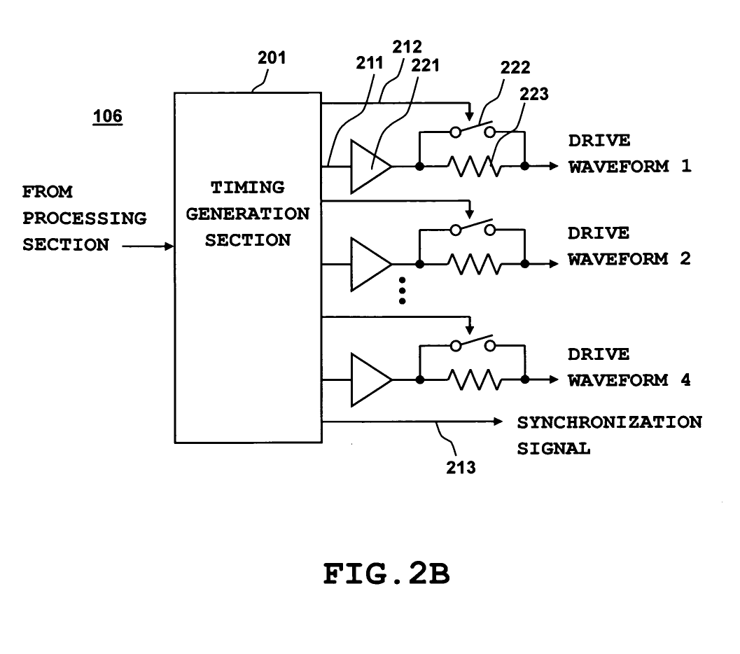

The difference in the drive section is described. The conventional bi-state drive section 1402 is replaced with a tri-state drive section 106 of the present invention. The related art uses binary driving, but the present invention is different in that a tri-state buffer 202 illustrated in FIG. 2A is used for driving in three states including a high impedance state.

The present invention is thus different in that, immediately after the change in drive voltage of a selected transmitting electrode, impedance of non-selected transmitting electrodes is temporarily increased, to thereby reduce a delay time to arrive at the current measurement section.

### Embodiment

Referring to the accompanying drawings, a preferred embodiment of the capacitive coordinate input device according to the present invention is described. For convenience sake, the following description provides a small number of transmitting electrodes 104 and receiving electrodes 105 and a small number of circuits and timings corresponding thereto. The features of the present invention, however, are not limited to the numbers described below. In the following, brackets < >, [ ], and ( ) represent a parent header, a child header, and a grandchild header, respectively.

### <Capacitive Coordinate Input Device>

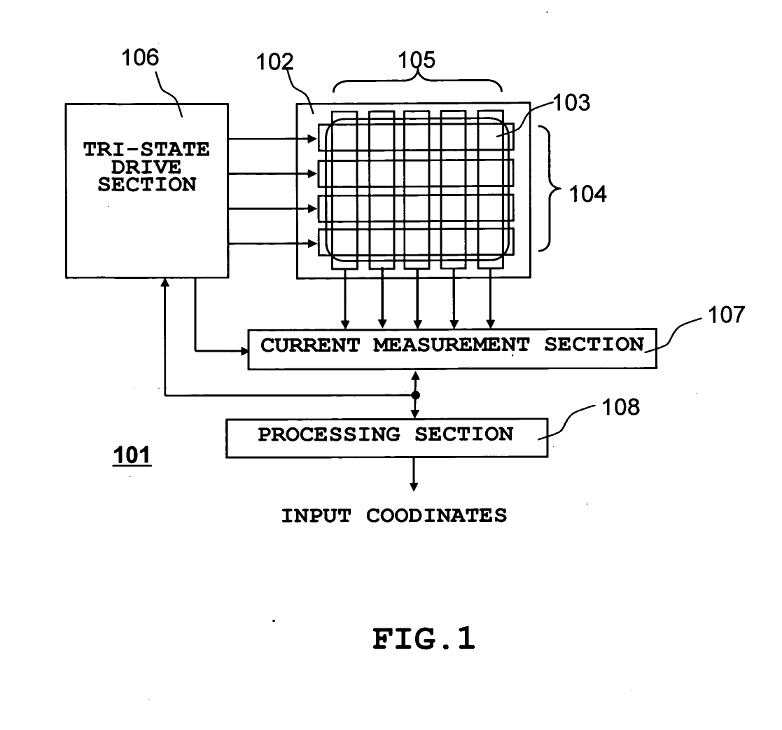

FIG. 1 is a block diagram of the capacitive coordinate input device according to the present invention. A capacitive coordinate input device 101 according to the present invention includes a support 102, the plurality of transmitting electrodes 104, the receiving electrodes 105, the tri-state drive section 106, a current measurement section 107, and a processing section 108. The plurality of transmitting electrodes 104 and the receiving electrodes 105 correspond to one dimension and the other dimension in a detection region 103 on the support 102, respectively. The tri-state drive section 106 drives the plurality of transmitting electrodes 104 so as to change a voltage of at least one transmitting electrode 104 that is sequentially selected from among the plurality of transmitting electrodes 104 and to temporarily increase drive impedance of non-selected transmitting electrodes 104 immediately after the change in voltage of the selected transmitting electrode 104. The current measurement section 107 measures a current or a charge amount supplied from the receiving electrode 105, in synchronization with the driving of the transmitting electrode 104. The processing section 108 determines input coordinates in the detection region 103 based on a value of the current or the charge amount measured by the current measurement section 107, and manages a status and a sequence of the overall capacitive coordinate input device 101.

### [Detection Region]

In the detection region 103 on the support 102, for example, the plurality of transmitting electrodes 104 corresponding to vertical coordinates and at least one receiving electrode 105 corresponding to horizontal coordinates are arranged to be orthogonal to one another. However, the transmitting electrodes 104 and the at least one receiving electrode 105 are not limited to this arrangement, and can be arranged freely as long as the transmitting electrode 104 and the receiving electrode 105 correspond to two-dimensional coordinates, such as oblique coordinates and circular coordinates of the angle and the distance from the origin. Those electrodes are conductive, and at the intersection of the transmitting electrode 104 and the receiving electrode 105, the electrodes are galvanically-isolated from each other by an insulating layer so as to be electrically capacitively coupled.

Therefore, if n is a natural number from 1 to N and m is a natural number from 1 to M for convenience sake of description, a periodic AC voltage applied to the n-th transmitting electrode 104 is transmitted to the m-th receiving electrode 105 via capacitive coupling at the intersection of the n-th transmitting electrode 104 and the m-th receiving electrode 105.

If the detection surface is affected by dirt or the like, an electric field via such approaching object enhances an electric field between the transmitting electrode 104 and the receiving electrode 105 because the approaching object itself has high impedance, thereby providing strong capacitive coupling between the transmitting electrode 104 and the receiving electrode 105, with the result that a large receiving current flows to the receiving electrode 105. On the other hand, when a detection target object of a relatively low impedance such as a human finger approaches, the capacitive coupling between the transmitting electrode 104 and the receiving electrode 105 is weakened because the action of absorbing the AC electric field generated from the transmitting electrode 104 is stronger, with the result that a small receiving current flows to the receiving electrode 105. Therefore, the dirt and the detection target of a human finger or the like can be distinguished easily.

The detection region described above is of a type that uses the change in electric field caused via an approaching object. However, the capacitive coordinate input device 101 and the capacitive coordinate input method according to the present invention may have a detection region 103 in which a gap between a layer of the transmitting electrode 104 and a layer of the receiving electrode 105 is changed by a pressure force of a pen, a finger, or the like, so as to detect a change in capacitance caused by the change in gap.

Here, for stable detection, the receiving electrode 105 is grounded or virtually grounded to suppress voltage fluctuation. What is transmitted to the receiving electrode 105 is thus a current rather than a voltage. Specifically, an AC electric field is generated at the intersection of a selected transmitting electrode 104 and a receiving electrode 105 because of capacitive coupling, with the result that a receiving current flows to the receiving electrode 105. On this occasion, the AC electric field at an intersection that an object approaches is changed, and hence the receiving current flowing to the receiving electrode 105 is changed.

Note that, in any method, the transmitting electrode 104 and the receiving electrode 105 need to be transparent in a case where the capacitive coordinate input device 101 is used by being placed on top of a display device. Accordingly, the transmitting electrode 104 and the receiving electrode 105 have a non-negligible resistance. Further, a wiring resistance around the detection region 103 is also not negligible in some cases. Therefore, a delay time is observed in the transmission of an AC current. The present invention shortens the delay time.

### <Tri-State Drive Section>

FIG. 2A illustrates a circuit configuration of the tri-state drive section 106. To supply each of the transmitting electrodes 104 with a drive waveform, the tri-state drive section 106 includes a timing generation section 201 and the tri-state buffers 202 corresponding to the transmitting electrodes.

### [Timing Generation Section]

The timing generation section 201 is activated by the processing section 108 to generate a logic signal 211 and a gate signal 212, which are necessary to drive the transmitting electrode for one frame, and a synchronization signal 213 necessary for current measurement of the current measurement section 107. In this example, the synchronization signal 213 contains a charge clear signal and a voltage measurement signal.

### [Tri-State Buffer]

The tri-state buffer 202 tri-state-drives the transmitting electrode 104 in high level, low level, and high impedance. The tri-state buffers 202 are each supplied with the logic signal 211 and the gate signal 212 from the timing generation section 201. The tri-state buffers 202 output drive waveforms 1 to 4, which are connected to transmitting electrodes 1 to 4, respectively.

### [Another Example of Tri-State Drive Section]

FIG. 2B illustrates another example of the tri-state drive section 106, in which, instead of the tri-state buffer 202, a resistor 223 and a switch 222 are connected in parallel and provided at an output of a bi-state buffer 221 so that a predetermined impedance may be provided when the switch 222 is turned OFF. The tri-state drive section 106 of FIG. 2B is configured such that, when the switch 222 is turned ON by the gate signal 212, the impedance is decreased sufficiently, and when the switch 222 is turned OFF by the gate signal 212, the impedance of the resistor 223 is used for driving. Compared with the configuration of FIG. 2A, a current makes a slight detour to the non-selected transmitting electrodes, but the influence of noise when the impedance is increased can be reduced.

### <Current Measurement Section>

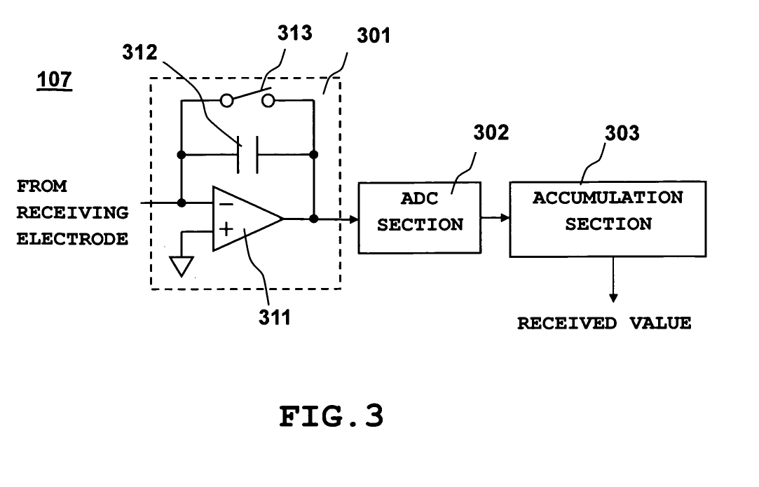

FIG. 3 illustrates a configuration of the current measurement section 107. The current measurement section 107 includes an integral section 301, an analog-to-digital converter (ADC) section 302, and an accumulation section 303. A plurality of the current measurement sections 107 of the same configuration are provided correspondingly to the at least one receiving electrode 105. Alternatively, the current measurement section 107 may be shared among the plurality of receiving electrodes 105 by using a time-division multiplexer or the like.

### [Integral Section]

The integral section 301 includes an operational amplifier 311, a capacitor 312, and a switch 313. The operational amplifier 311 forms an integral circuit by negative feedback through the capacitor 312 from an output terminal to a negative input terminal thereof. The integral section 301 integrates the receiving current from the receiving electrode 105 to convert the receiving current into a voltage value corresponding to the charge amount. A reference voltage is 0 V, which is connected to a positive input terminal of the operational amplifier 311. The capacitor 312 is connected to the switch 313 at its both terminals, and is initialized by the charge clear signal from the timing generation section 201.

### [ADC Section]

The ADC section 302 converts an output voltage of the integral section 301 into a digital value. The ADC section 302 performs the conversion at a timing at which the voltage measurement signal from the timing generation section 201 becomes true.

### [Accumulation Section]

The accumulation section 303 accumulates the digital values from the ADC section 302 corresponding to a plurality of voltage changes of each transmitting electrode. The accumulation section 303 performs accumulative addition at a voltage rising edge and accumulative subtraction at a voltage falling edge. Note that, the ADC section 302 and the accumulation section 303 may be integrated as a sigma-delta analog-to-digital converter or the like.

Further, the order of the ADC section 302 and the accumulation section 303 may be interchanged so as to convert the result of analog accumulation by the accumulation section 303 into a digital value in the ADC section 302.

### [Offset Removal]

In the circuit of the current measurement section 107 or in the calculation of the processing section 108, if a value close to a measured value obtained when a detection target object is not approaching is subtracted as an offset, the change in measured value caused by the approach of the object can be measured more accurately. The offset value for the measurement may be a common value among the transmitting electrodes 104 to be selected and the plurality of receiving electrodes 105, and may be an individually-optimized value. The use of an individually-optimized value enables good detection even when the detection region 103 is dirty in part, by removing the influence thereof.

### <Processing Section>

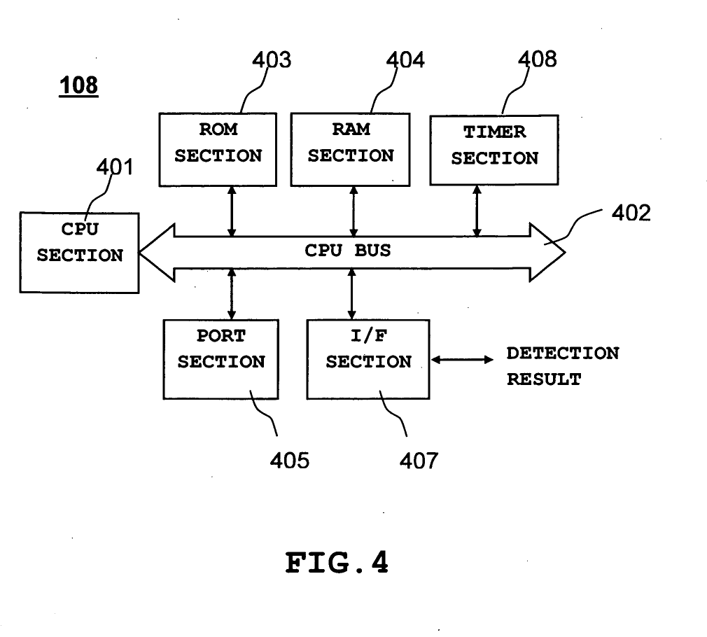

FIG. 4 illustrates an example of the processing section 108. The processing section 108 is implemented by a general-purpose microprocessor. The processing section 108 includes a CPU section 401, a ROM section 403, a RAM section 404, a port section 405, an I/F section 407, and a timer section 408, all of which are connected via a CPU bus 402.

The CPU section 401 performs information processing and calculation. The ROM section 403 stores programs to be processed by the CPU. The RAM section 404 temporarily stores conditions, parameters, and other information necessary for the processing. The port section 405 outputs and inputs a status and a parameter to and from the tri-state drive section 106 and the current measurement section 107. The I/F section 407 is an interface to the outside of the capacitive coordinate input device 101, for outputting the detection result of coordinates or the like. The timer section 408 generates a reference signal for an operation timing of the CPU section 401.

The processing section 108 compares the change in current value measured by the current measurement section 107 with a threshold to determine whether or not the coordinates have been input, and also calculates the input coordinates based on weighted average or the like.

Further, the processing section 108 manages a status and a sequence of the overall capacitive coordinate input device 101. The status as used herein refers to conditions of the respective sections during current measurement and the like, and the sequence as used herein refers to an activation for detection at predetermined time intervals or the like.

### <Capacitive Coordinate Input Method>

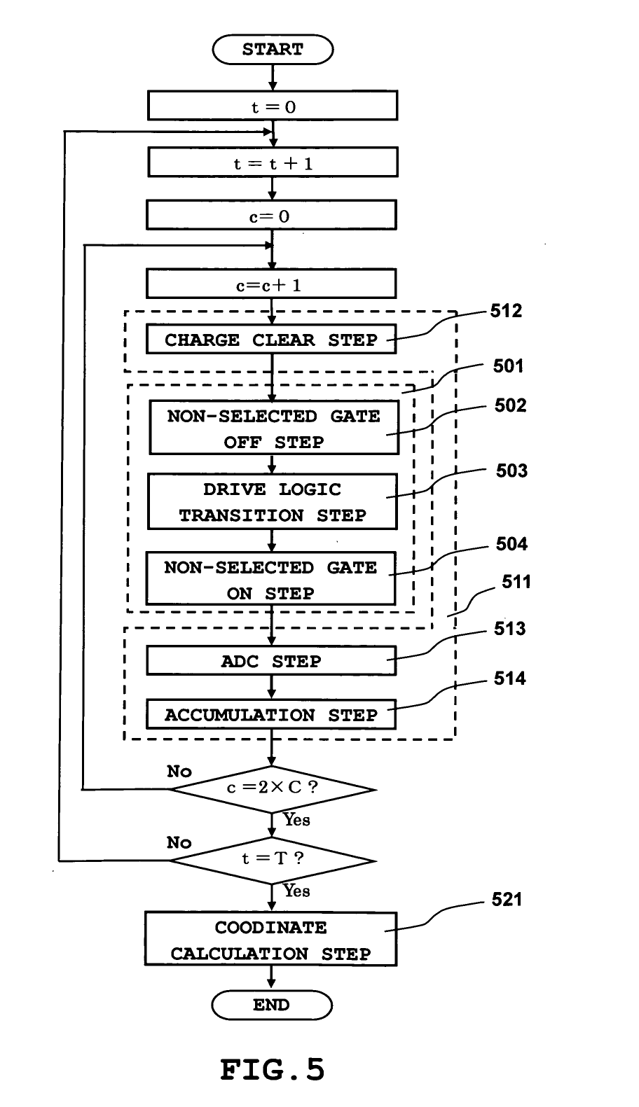

FIG. 5 is a flow chart illustrating an example of a process of the capacitive coordinate input method according to the present invention. The capacitive coordinate input method according to the present invention includes a tri-state driving step 501, a current measurement step 511, and a coordinate calculation step 521. In the tri-state driving step 501, the plurality of transmitting electrodes 104 corresponding to one dimension in the detection region 103 for detecting the approach of an object are driven to sequentially select one transmitting electrode 104 from among the plurality of transmitting electrodes 104 so as to change a voltage thereof and to temporarily increase drive impedance of non-selected transmitting electrodes 104 immediately after the change in voltage of the selected transmitting electrode 104. In the current measurement step 511, a current or a charge amount supplied from at least one receiving electrode 105 corresponding to another dimension is measured in synchronization with the driving of the plurality of transmitting electrodes 104. In the coordinate calculation step 521, based on the obtained current value or charge amount, whether or not the coordinates have been input to the detection region 103 is determined and the input coordinates are then determined.

In order to improve the SN ratio, the tri-state driving step 501 and the current measurement step 511 are repeated a plurality of times with the same transmitting electrode 104 selected. In general, the capacitance formed at each intersection of the transmitting electrode 104 and the receiving electrode 105 is as small as about 1 to 100 pF, and a receiving current flowing to the receiving electrode 105 and its change are also weak. Therefore, the detection of the receiving current flowing to the receiving electrode 105 is performed by accumulating currents in a plurality of cycles applied from the transmitting electrode 104.

Note that, the receiving current flowing to the receiving electrode 105 is usually an AC current, and hence if the currents are simply accumulated, the accumulated values are canceled. To avoid the problem, the accumulation section 303 accumulates the currents while switching the polarity in synchronization with the phase of the AC current. In the example of the flow of FIG. 5, both of the rising edge and the falling edge of drive logic are used, and hence the tri-state driving step 501 and the current measurement step 511 are repeated until the count of the repeated number of c, which is a natural number from 1 to C, takes twice the number of cycles C.

Each electrode itself has a resistance and a capacitance and causes high-frequency attenuation, whereas low-frequency attenuation occurs at the intersection of the electrodes because of their series capacitances. In view of the fact, it is desired that a voltage applied to the transmitting electrode have a frequency which causes less attenuation.

Further, a transmitting electrode 104 to be driven is sequentially selected from among all the transmitting electrodes 104 in the detection region 103, to drive the transmitting electrodes 104 in the entire detection region 103. Accordingly, in the example of the flow of FIG. 5, the tri-state driving step 501 and the current measurement step 511 are repeated T times by counting t (t is a natural number from 1 to T). Therefore, T usually matches the number N of the transmitting electrodes 104.

The transmitting electrodes 104 in the entire detection region 103 are driven to measure the current flowing to the receiving electrode 105, and then the coordinate calculation step 521 is performed. This is an example, and there is no particular limitation on the overall flow. For example, the coordinate calculation step 521 may be performed every selection period, or parallel processing may be performed such that the next tri-state driving step 501 and current measurement step 511 are executed while executing the coordinate calculation step 521.

The overall flow of FIG. 5 is repeated periodically in response to an activation instruction from the processing section 108.

### [Tri-State Driving Step]

The tri-state driving step 501 includes a non-selected gate OFF step 502 of increasing output impedance of the tri-state buffers 202 which drive the non-selected transmitting electrodes 104, a drive logic transition step 503 of changing a voltage of the selected transmitting electrode, and a non-selected gate ON step 504 of decreasing the output impedance of the tri-state buffers which drive the non-selected transmitting electrodes. FIG. 5 illustrates an example in which the non-selected gate OFF step 502 is prior to the drive logic transition step 503. However, the non-selected gate OFF step 502 and the drive logic transition step 503 may be performed at substantially the same time.

### [Current Measurement Step]

The current measurement step 511 includes a charge clear step 512 prior to the tri-state driving step 501, and an ADC step 513 and an accumulation step 514 after the tri-state driving step 501, to measure a current supplied from the receiving electrode 105. In the charge clear step 512, the switch 313 is turned ON to clear charges of the capacitor 312 of the integral section 301. In the ADC step 513, an output voltage of the integral section 301 is converted into a digital value. In the accumulation step 514, the digital values obtained in the ADC step 513 are accumulated by the accumulation section 303 for each selected transmitting electrode 104 or for each combination of selected transmitting electrodes 104.

### [Coordinate Calculation Step]

In the coordinate calculation step 521, based on the current value determined in the current measurement step 511, which depends on capacitive coupling at each intersection of the electrodes corresponding to the two-dimensional coordinates, or based on a transition of the current value, whether or not a detection target object is approaching is determined and the position thereof is then calculated through weighted average or the like.

### <Operation Timings of Tri-State Driving Step and Current Measurement Step>

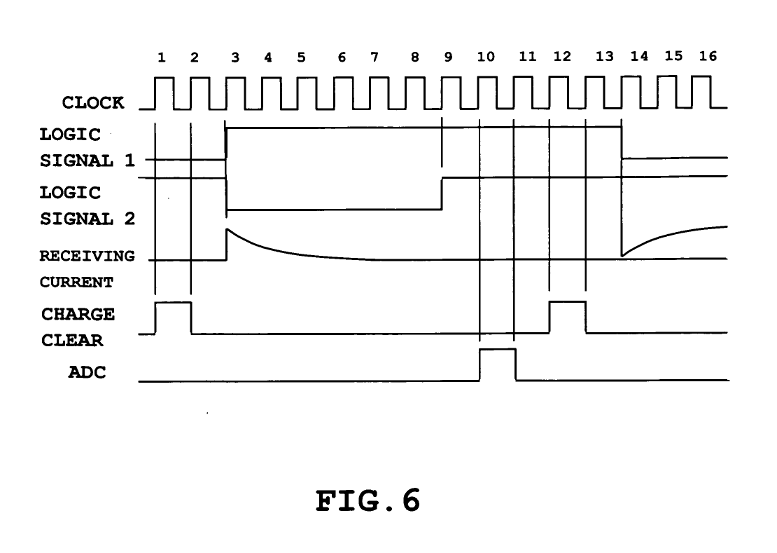

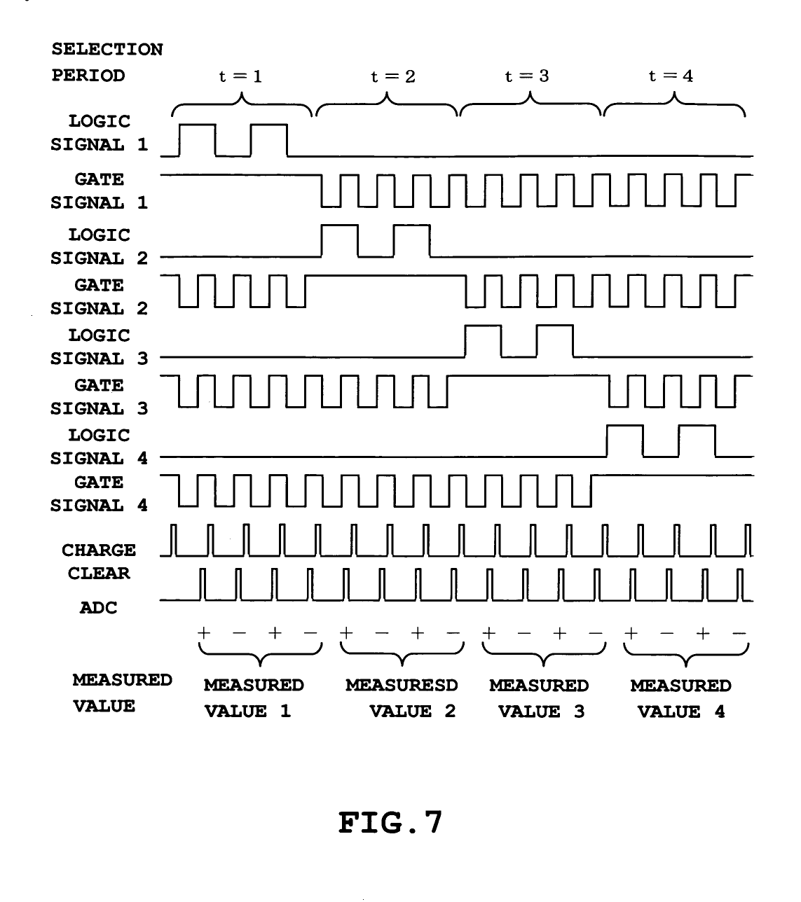

FIGS. 6 and 7 illustrate a specific example of operation timings of the tri-state driving step 501 and the current measurement step 511, which are the features of the present invention. FIG. 6 illustrates detailed timings with respect to the rising edge of the first cycle in the first selection period 1. FIG. 7 illustrates timings of scanning of the entire detection region 103. FIGS. 6 and 7 illustrate the timing relationships among the logic signal 211, the gate signal 212, and the synchronization signal 213 generated by the timing generation section 201 as one example. In the timing charts, the logic signals 1 to 4 and the gate signals 1 to 4 show signals connected to the tri-state buffers 202 from the timing generation section 201 in correspondence with the respective transmitting electrodes 104.

In FIG. 6, the abscissa axis is a common time axis, and the ordinate axis represents logic level. The upper side is true and the lower side is false. Note that, the receiving current has an analog current value.

### (Clock)

The timing generation section 201 generates a signal by counting a clock as a time reference.

### (Selected Transmitting Electrode)

The logic signal 1 is a logic signal to be input to the tri-state buffer 202 which is connected to the transmitting electrode 1 as an example of the selected transmitting electrode 104. The logic signal 1 exhibits the false level in the initial state, and rises to the true level at the third rising edge of the clock of FIG. 6. The true level of the logic signal is maintained until the 14th rising edge of the clock. Although not illustrated, a gate signal which is connected to the tri-state buffer 202 connected to the selected transmitting electrode 1 is always true.

### (Non-Selected Transmitting Electrode)

As an example for the non-selected transmitting electrode 104, the gate signal 2 is a signal to be connected and input to the gate of the tri-state buffer 202 which is connected to the transmitting electrode 2. The gate signal 2 is changed from true to false at substantially the same timing of the change of the selected logic signal 1. The gate signal 2 maintains the false level until the receiving current converges almost completely, and then returns to true at the 9th rising edge of the clock. The reason why the gate signal 2 returns to true at that time is that, if the voltage of the transmitting electrode 2 varies due to noise or the like, the noise flows into the receiving electrode from the transmitting electrode 2 to prevent accurate detection. Although not illustrated, a logic signal which is connected to the tri-state buffer 202 connected to the non-selected transmitting electrode 2 is kept at a constant level without change.

The same holds true for the transmitting electrodes other than the transmitting electrode 2.

### (Charge Clear)

Before the voltage of the selected transmitting electrode is changed, in the first cycle period of the clock, namely in the charge clear step 512, the charge clear signal is changed to true to short-circuit both ends of the capacitor 312 of the integral section 301.

### (ADC)

When a time of one cycle of the clock has elapsed after the gate signals corresponding to the non-selected transmitting electrodes, including the gate signal 2, were changed to true, voltage measurement is performed by the ADC section 302 in the ADC step 513 in response to the 10th rising edge of the clock.

In FIG. 7, the abscissa axis is a common time axis, and the ordinate axis represents logic level of each signal, in which the upper side is true and the lower side is false. FIG. 7 illustrates the timings of the scanning of the entire detection region, which is performed, based on the timings of FIG. 6, by means of drive logic inversion, the repetitive plurality of cycles, and the switch of a transmitting electrode to be selected.

### (Line-Sequential Driving)

As illustrated in FIG. 7, in this embodiment, four transmitting electrodes 1 to 4 are line-sequentially driven for the respective selection periods t=1 to 4. In other words, the transmitting electrode 1 selected in the selection period 1 is driven by the logic signal 1 and the gate signal 1. On this occasion, the non-selected transmitting electrodes 2 to 4 are driven so that the logic signals are maintained at a constant level without change while the gate signals become false temporarily immediately after the change in logic signal corresponding to the selected transmitting electrode. The same holds true for the selection periods 2 to 4.

### (Detection in Plurality of Cycles)

Further, in the selection period 1, the selected logic signal is changed in voltage for two cycles in order to improve the SN ratio. In other words, the voltage is changed four times, that is, at the rising edge, the falling edge, the rising edge, and the falling edge. In each of the four voltage changes, the current is measured by the current measurement section 107 in the current measurement step 511, and four measured values are accumulated. On this occasion, in the accumulation step 514, the accumulation section 303 adds the measured values corresponding to the rising edges, and subtracts the measured values corresponding to the falling edges. The accumulation in the accumulation step 514 is performed for each selected transmitting electrode, to thereby obtain measured values 1 to 4 that are accumulated corresponding to the selection periods 1 to 4.

### <Action and Effect of the Invention>

Now, the action and effect of the present invention are described.

### [Drive Waveform]

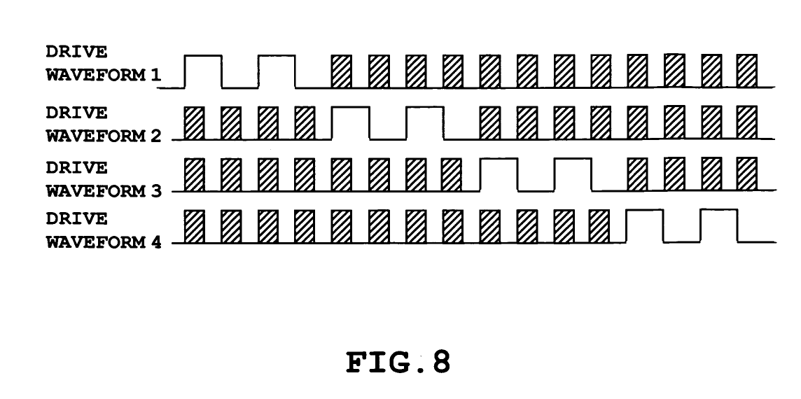

FIG. 8 illustrates the drive waveforms 1 to 4 for driving the transmitting electrodes 1 to 4, respectively, in the configuration and the method described above. In FIG. 8, the abscissa axis is a common time axis, and the ordinate axis represents voltage level.

The drive waveform shows that the logic signal is output to the transmitting electrode 104 as it is while the gate signal of the tri-state buffer 202 is true, and when the gate signal becomes false, the impedance is increased and the voltage becomes indeterminate. Therefore, the voltage change for two cycles is output to each of the transmitting electrodes 104 selected by line-sequential driving, and each voltage of the non-selected transmitting electrodes 104 becomes indeterminate temporarily immediately after the change in voltage of the selected transmitting electrode. In FIG. 8, the hatched area indicates that the voltage is indeterminate in that period.

### [Equivalent Circuit of Detection Region]

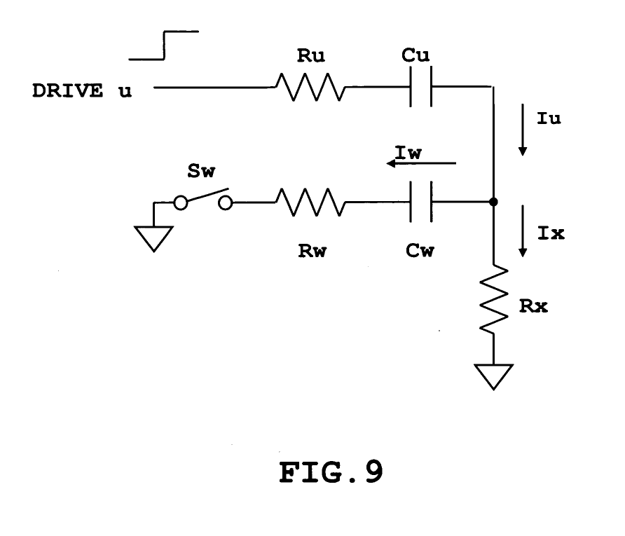

FIG. 9 is a conceptual diagram summarizing equivalent circuits of the detection region 103. In FIG. 9, drive u represents a signal to be connected to a selected transmitting electrode 104. A resistor Ru represents a resistance of wiring to the selected transmitting electrode 104 and a resistance of the electrode itself. A capacitor Cu represents a capacitance at the intersection of the selected transmitting electrode 104 and the receiving electrode 105. A capacitor Cw represents a capacitance at the intersection of a non-selected transmitting electrode 104 and the receiving electrode 105. A resistor Rw represents a resistance of wiring to the non-selected transmitting electrode 104 and a resistance of the electrode itself. A switch Sw switches impedance of the non-selected transmitting electrode 104. A resistor Rx represents a resistance of wiring to the receiving electrode 105 and a resistance of the receiving electrode 105 itself.

In the conventional capacitive coordinate input device or the conventional capacitive coordinate input method, the switch Sw continues to be ON. Accordingly, when a changing sweep voltage is applied to the drive u, a current Iu supplied from the selected drive electrode (transmitting electrode) is divided into a current Iw flowing to the non-selected transmitting electrode 104 and a current Ix flowing directly to the receiving electrode 105. The current flowing into the non-selected transmitting electrode 104 at this time is accumulated in the capacitor Cw. After that, the capacitor Cu cuts off a direct component to eliminate the current Iu, and the charges accumulated in the capacitor Cw flow into the receiving electrode 105. This way, part of the current supplied from the selected transmitting electrode 104 makes a detour to the non-selected transmitting electrode 104 to flow into the receiving electrode 104, resulting in a long delay time.

On the other hand, according to the present invention, the switch Sw is temporarily opened immediately after the change in voltage of the selected transmitting electrode 104, and hence the current Iu supplied from the selected transmitting electrode 104 flows directly into the receiving electrode 105 without making a detour to the non-selected transmitting electrode 104. Therefore, the delay time can be shortened.

### [Calculation Results]

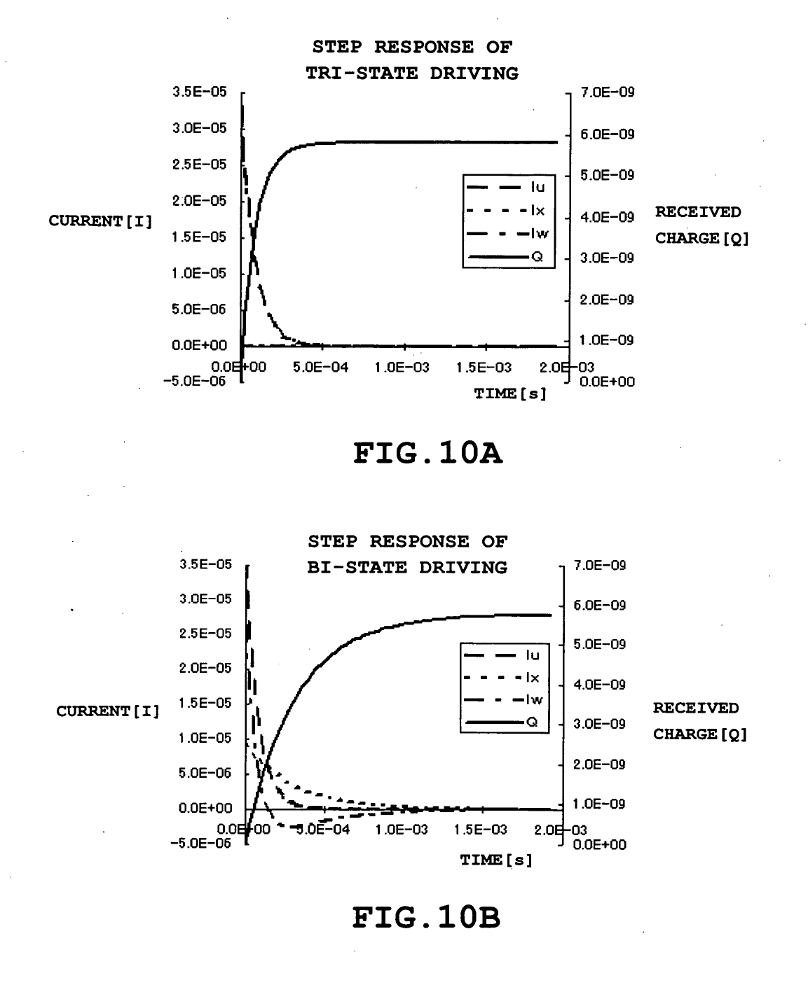

FIGS. 10A and 10B illustrate the results of calculating temporal changes in current flowing in the circuit illustrated in FIG. 9. In FIGS. 10A and 10B, the broken line represents the current Iu supplied from the selected transmitting electrode 104, the dotted line represents the current Ix that flows into the receiving electrode 105, the dashed-dotted line represents the current Iw that makes a detour to the non-selected transmitting electrodes 104, and the solid line represents a charge amount Q that is obtained by integrating the currents flowing into the receiving electrode 105.

In the calculation, the number of transmitting electrodes is 30, the number of receiving electrodes is 24, a wiring resistance of each transmitting electrode is 82 kΩ, a wiring resistor of each receiving electrode is 195 kΩ, and a capacitance at an intersection of a transmitting electrode and a receiving electrode is 40 pF. In this case, in order to aggregate the plurality of transmitting electrodes and the plurality of receiving electrodes, the calculation is performed assuming those electrodes are connected in parallel. Then, the results show that the resistor Ru is 82 kΩ, the capacitor Cu is 960 pF, the capacitor Cw is 28 nF, the resistor Rw is 2.8 kΩ, and the resistor Rx is 8.1 kΩ.

FIG. 10A shows the step response of tri-state driving, in which the calculation is made by turning OFF the switch Sw, assuming the capacitive coordinate input device and the capacitive coordinate input method according to the present invention. FIG. 10B shows the step response of bi-state driving, in which the calculation is made by turning ON the switch Sw, assuming the conventional capacitive coordinate input device and the conventional capacitive coordinate input method. In this example, in the present invention, the charge amount Q converges in a shorter period of time of about 1/3.6, compared to the related art.

As described above, according to the present invention, immediately after the change in voltage of a selected transmitting electrode 104, non-selected transmitting electrodes 104 are increased in impedance to eliminate a current detour to the non-selected transmitting electrodes 104, to thereby significantly shorten a delay time to arrive at the receiving electrode 105.

Described above are the configuration and the method in which, as illustrated in FIGS. 10A and 10B, the transmitting electrodes 104 are line-sequentially selected one by one, and all the non-selected transmitting electrodes 104 are increased in impedance temporarily immediately after the change in voltage of the selected transmitting electrode 104, followed by measuring and accumulating the current flowing into the receiving electrode 105 at the rising edge and the falling edge of the voltage of the selected transmitting electrode 104. However, the capacitive coordinate input device 101 and the capacitive coordinate input method according to the present invention are not limited to the above.

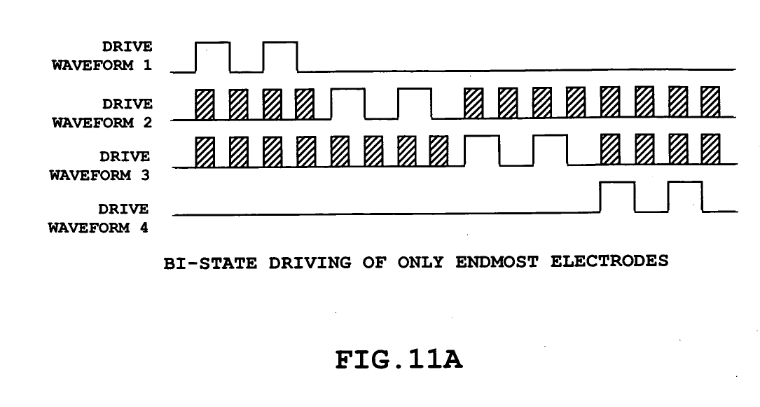

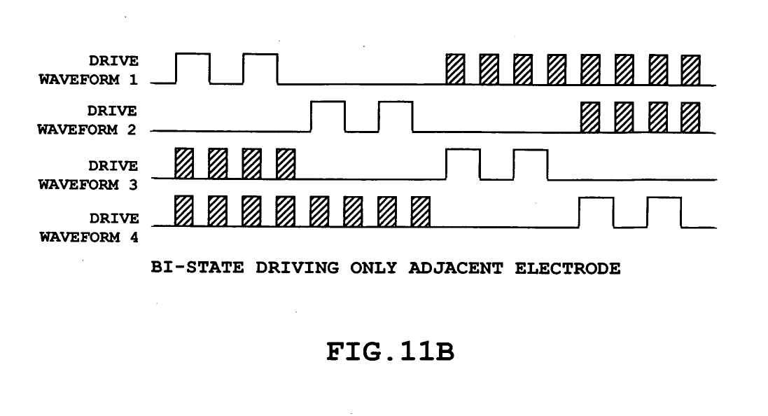

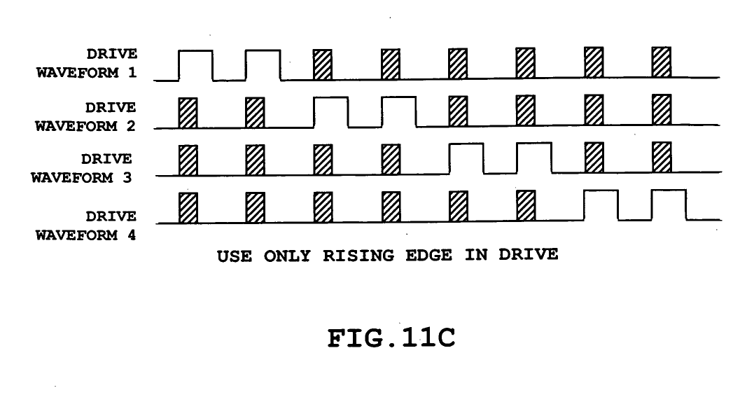

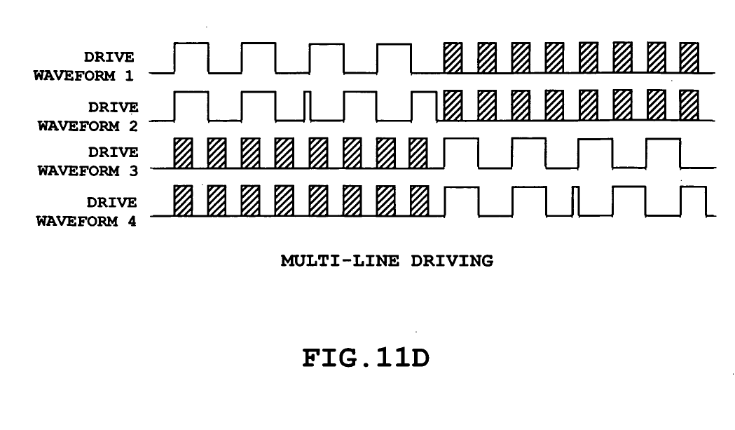

FIGS. 11A to 11D illustrate other examples of the drive waveform. In FIGS. 11A to 11D, similarly to FIG. 8, the abscissa axis is a common time axis, and the ordinate axis represents a voltage of each transmitting electrode. In FIGS. 11A to 11D, the hatched area indicates that the voltage is indeterminate in that period because of high impedance.

In FIG. 11A, the transmitting electrodes are driven such that the endmost transmitting electrodes are not increased in impedance, thereby reducing the influence of external noise.

Alternatively, as illustrated in FIG. 11B, the transmitting electrodes may be driven such that a transmitting electrode adjacent to a selected transmitting electrode are not increased in impedance, thereby reducing radiation noise, which is caused by the change in voltage of the selected transmitting electrode.

As a further example, as illustrated in FIG. 11C, the transmitting electrodes may be driven such that non-selected transmitting electrodes are temporarily increased in impedance only immediately after the voltage rising edge or the voltage falling edge of the selected transmitting electrode.

As illustrated in FIG. 11D, even in the case of selecting a plurality of transmitting electrodes for driving, non-selected transmitting electrodes may be increased in impedance immediately after the change in voltage of the selected transmitting electrodes so that a delay time to the receiving electrode may be reduced. The example of FIG. 11D uses a Hadamard matrix for driving. It should be understood that, in this case, correlation calculation or inverse matrix calculation needs to be performed based on measured values of the currents to the receiving electrodes.

Further, the drive waveforms are exemplified above for the case of driving in response to a rising edge followed by a falling edge. However, it should be understood, too, that the reverse phase can also be used.

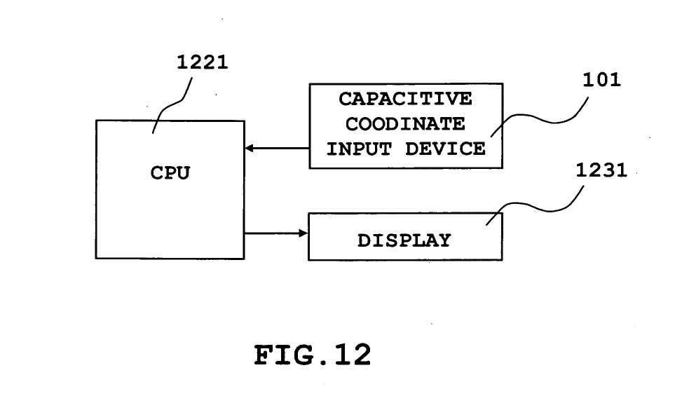

As illustrated in FIG. 12, the capacitive coordinate input device 101 according to the present invention can be connected to a CPU 1221 for controlling a display 1231, thereby providing an information device.

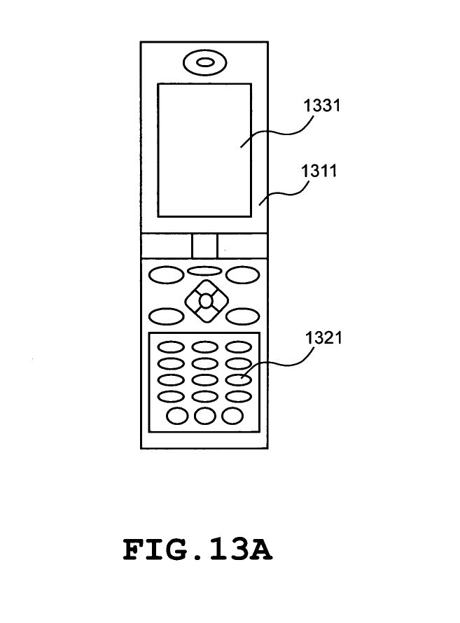

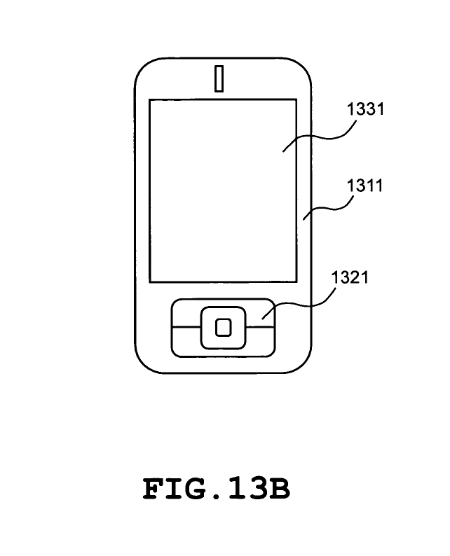

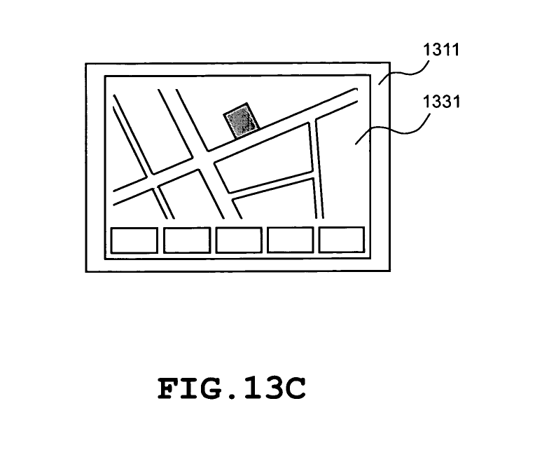

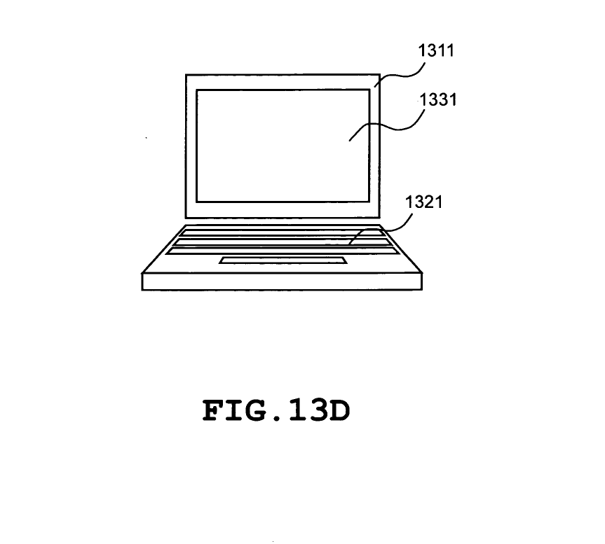

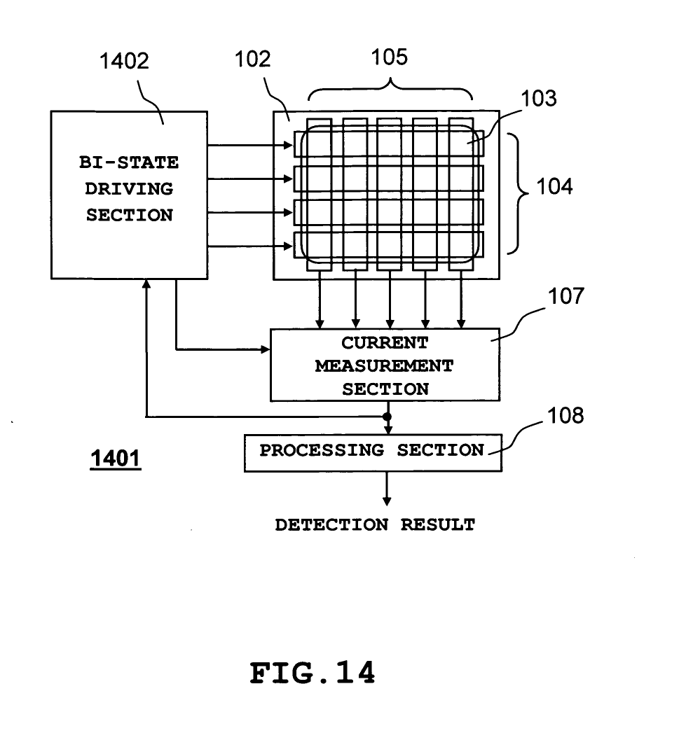

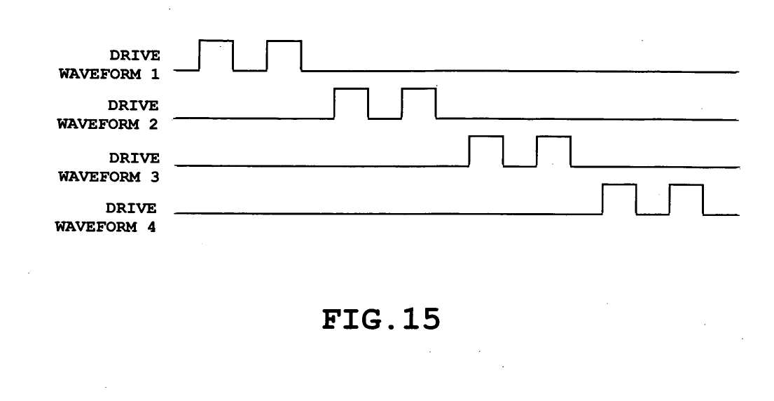

Specifically, the capacitive coordinate input device 101 according to the present invention can be used to realize an information device, such as a mobile phone or a computer, capable of noise-resistant, stable and smooth operation, for example, a mobile phone illustrated in FIG. 13A, a multimedia player illustrated in FIG. 13B, a navigation system illustrated in FIG. 13C, a computer illustrated in FIG. 13D, or other similar equipment, by placing a transparent detection region 103 on top of a display device of such equipment to form a touch screen 1331.

The configuration of the information devices illustrated in FIGS. 13A to 13D is implemented by a case 1311 for protecting the information device, the touch screen 1331 for outputting information, the capacitive coordinate input device 101 according to the present invention for receiving an input from the detection region 103, which is placed on the display 1231, and identifying the approach of an object and the position thereof, and the CPU 1221 for controlling an input from the capacitive coordinate input device and an output to the display 1231. Further, as illustrated in FIGS. 13A, 13B, and 13D, the information device may be provided with a keyboard 1321.

What is claimed is:

1. A capacitive coordinate input device for inputting coordinates by input means including a finger and a pen, comprising:
a support;
a plurality of transmitting electrodes corresponding to one dimension in a detection region on the support and a receiving electrode corresponding to another dimension;
a tri-state drive section for driving the plurality of transmitting electrodes so as to change a voltage of at least one transmitting electrode that is selected from among the plurality of transmitting electrodes and to temporarily increase drive impedance of non-selected transmitting electrodes immediately after the change in the voltage of the at least one selected transmitting electrode;
a current measurement section for measuring one of a current and a charge amount supplied from the receiving electrode, in synchronization with the driving of the plurality of transmitting electrodes; and
a processing section for determining input coordinates in the detection region based on one of a value of the current and the charge amount measured by the current measurement section.

2. A capacitive coordinate input device according to claim 1, wherein the tri-state drive section comprises a tri-state buffer.

3. A capacitive coordinate input method for inputting coordinates by input means including a finger and a pen, comprising:
tri-state-driving a plurality of transmitting electrodes corresponding to one dimension in a detection region for detecting approach of an object, so as to change a voltage of at least one transmitting electrode that is selected from among the plurality of transmitting electrodes and to temporarily increase drive impedance of non-selected transmitting electrodes immediately after the change in the voltage of the at least one selected transmitting electrode;
performing current measurement on one of a current and a charge amount supplied from a receiving electrode corresponding to another dimension in the detection region, in synchronization with the tri-state driving of the plurality of transmitting electrodes; and
determining input coordinates in the detection region based on one of a value of the current and the charge amount obtained by the current measurement.

4. A capacitive coordinate input method according to claim 3, wherein the tri-state-driving comprises avoiding increasing drive impedance of endmost transmitting electrodes.

5. A capacitive coordinate input method according to claim 3, wherein the tri-state-driving comprises avoiding increasing drive impedance of a transmitting electrode adjacent to the at least one selected transmitting electrode.

6. An information device, comprising an input device that complies with the capacitive coordinate input device according to claim 1.
